(19) United States
(12) Patent Application Publication
(10) Pub. No.: US 2025/0391707 A1
(43) Pub. Date: Dec. 25, 2025

(54) METHOD AND SYSTEM FOR 3D RECONSTRUCTION OF WAFER STRUCTURE BY DIAGONAL MILLING

(71) Applicant: Applied Materials Israel Ltd., Rehovot (IL)

(72) Inventors: Guy Eytan, Kfar-Aviv (IL); Dan Segal, Rehovot (IL); Ohr Lahad, Rehovot (IL); Konstantin Chirko, Rehovot (IL); Alon Litman, Ness Ziona (IL); Ron Bar-Or, Ramat-Gan (IL); Haim Feldman, Nof-Ayalon (IL)

(73) Assignee: Applied Materials Israel Ltd., Rehovot (IL)

(21) Appl. No.: 18/754,126

(22) Filed: Jun. 25, 2024

(51) Int. Cl. H01L 21/66; H01J 37/06; H01J 37/22; H01J 37/28; H01J 37/304; H01J 37/305; H01L 21/67

(52) U.S. Cl. CPC H01L 22/12; H01J 37/06; H01J 37/222; H01J 37/304; H01J 37/3053; H01L 21/67288; H01J 37/28; H01J 2237/2814; H01J 2237/31749

(57) ABSTRACT

Disclosed are system and method for metrology of 3D structural elements of a wafer by projecting, on a subset of the 3D structural elements, a focused ion beam (FIB) at a predefined diagonal angle, thereby generating a diagonal cut in each of the subset of sites, scanning each of the diagonal cuts using a scanning electron microscope (SEM), generating a reconstruction of the one or more 3D structural elements or a component thereof based on the SEM image and performing metrology measurements on the reconstruction.

### TECHNICAL FIELD

The present disclosure relates generally to integration of focused ion beam (FIB) and scanning electron microscopy (SEM) technologies for 3D imaging and metrology of wafers.

### BACKGROUND OF THE INVENTION

Scanning electron microscope (SEM) produces images of a sample (such as wafer samples) by scanning the surface with a focused beam of electrons. The electrons interact with atoms in the sample, producing various signals that contain information about the surface topography and composition of the sample. However, due to the 3D structure trend of the wafer industry and the 2D imaging nature of the SEM a solution for 3D metrology is required.

Solutions to 3D metrology have been developed such as CD-SAXS, optical scatterometry and TEM. However, the current solutions either:
1. Do not cover the whole application space: CD-SAXS (logic), TEM (Memory), Scatterometry (Memory and partially logic); and/or
2. Take long time to results (TEM and CD-SAXS), and/or
3. Are destructive and cannot be conducted in-line.

Focused ion beam, also known as FIB, is a technique used particularly in the semiconductor industry. While the SEM uses a focused beam of electrons to image the sample in the chamber, a FIB setup uses a focused beam of ions instead. FIB can also be incorporated in a system with both electron and ion beam columns, allowing the same feature to be investigated using either of the beams.

The FIB can be operated at low beam currents for imaging or at high beam currents for site specific sputtering or milling. However, unlike SEM, FIB is inherently destructive to the specimen.

Until recently, the overwhelming usage of FIB has been in the semiconductor industry. Such applications as defect analysis, circuit modification, photomask repair and transmission electron microscope (TEM) sample preparation of site specific locations on integrated circuits have become commonplace procedures.

The latest FIB systems have high resolution imaging capability; this capability coupled with in situ sectioning has eliminated the need, in some cases, to examine FIB sectioned specimens by separate electron imaging. SEM imaging is still required for the highest resolution imaging and to prevent damage to sensitive samples.

A combination of SEM and FIB columns onto the same chamber has been disclosed, however till today SEM-FIB imaging is both destructive and time consuming and does not produce a full 3D reconstruction with nanometric resolution.

There therefore remains a need for a metrology tool which enables high-resolution, 3D inspection of 3D structural elements, which tool is fast, and preferably sufficiently nondestructive to be incorporated in line.

### BRIEF SUMMARY OF THE INVENTION

According to some embodiments, there is provided a method of system for 3D metrology of wafers. Advantageously, the herein disclosed method and system provide a unique integration of the benefits of each of focused ion beam (FIB) technology and scanning electron microscope (SEM) technology to obtain a tool, which enables the entire process for providing 3D metrology of 3D structural elements, at nano-scale resolution, and in a fast and relatively non-destructive manner.

In short, the system and method disclosed herein utilizes a FIB-tool configured to mill an area of the wafer at a predetermined diagonal angle to thereby generate one or more diagonal cuts in the 3D structural elements, present in the area. As a result of the diagonal cut, the structural elements in the area are each cut at different heights thereof, thereby exposing layers of the 3D structure at different depths thereof.

In addition, the herein, the FIB-tool advantageously has control of the scan rotation enabling cutting the structural elements with a controlled plane rotation (w). According to some embodiments, the plane rotation angle (w) may be set/selected prior to the cutting of the structural element. According to some embodiments, the plane rotation angle (w) may be set/selected based on one/or features of the structural element and or portions thereof, e.g., based on their height, width substructures or the like. According to some embodiments, the plane rotation angle (w) may be changed/adjusted between different cuts to thereby expose different rotational planes thereof.

The exposed layers can then be scanned using high-quality SEM to obtain one or more high-resolution images. That is, the herein disclosed method and system advantageously has the ability to fully reconstruct a 3D volume of a structure and measure it with a 3D resolution of ˜ 1 nm.

Based on the one or more images, a 3D structure can advantageously be reconstructed by combining/assembling the layers of the plurality of structures, each layer showing a different depth of the structure.

Additionally or alternatively, a plurality of diagonal cuts can be made, wherein a SEM image is taken after each cut. In this way, a same 3D structure can be imaged at different heights/depths thereof. Such sequential delayering can advantageously increase the reconstruction resolution as compared to a single cut, albeit at the expense of time. Sequential delayering can be particularly advantageous in case various type 3D structural elements are included in the area, since otherwise the different layers exposed cannot be assembled into a single 3D structural element. According to some embodiments, the SEM imaging may be cold field emission (CFE)-SEM, thereby allowing measuring the surface with low-energy electrons, and in turn advantageously provide high depth resolution, and high lateral-resolution-SEM imaging.

Advantageously, once the structural element has been reconstructed, various metrology measurement can be carried out in order to determine a characteristic and/or dimension of the 3D structural elements and/or the component thereof (e.g., a nanosheet of a gate-all-around (GAA) transistor). Based on the metrology measurements a quality/attribute of the manufacturing process of the wafer can then be determined.

Accordingly, based on a single cut in one or more areas of the wafer, the 3D structure of a wafer can be measured at high resolution and while sacrificing only a small (negligible) area of the wafer (e.g., less than 5% of the wafer).

As a further advantage, the herein disclosed method may be conducted via one stand-alone tool, thus ensuring an integrative and streamlined process.

Due to the fast and minimally destructive nature of the herein disclosed method and system, it can advantageously be incorporated in-line to the manufacturing process, while providing a 3D reconstruction with nanometric resolution, also referred to herein as a section view. That is, the herein disclosed method and system provide the ability to fully reconstruct a 3D volume and measure the volume with a 3D resolution of about 1 nm.

According to some embodiments, there is provided a method for metrology of a wafer including a plurality of sites each site including one or more 3D structural element, the method including the steps of:
depositing, on each of a subset of the plurality of sites, a deposition layer using a gas injection system (GIS) and a charged-particle gun,
projecting, on each of a subset of the plurality of sites, a focused ion beam (FIB) at a predefined mechanical angle (a) and at a controllable plane rotation (w), thereby generating a diagonal cut in each of the subset of sites,
scanning each of the diagonal cuts using a scanning electron microscope (SEM) configured to provide a top view of the subset of sites, to obtain an image at different depths of each of the subset of sites;
applying an algorithm on the image, the algorithm configured to generate a reconstruction of the one or more 3D structural elements or a component thereof in the subset of sites;
determining a characteristic and/or dimension of the one or more 3D structural elements and/or the component thereof in the subset of sites; and
determining a quality/attribute of a wafer manufacturing process based on the determined characteristic and/or dimension of the one or more 3D structural elements and/or component thereof, while maintaining the integrity of the plurality of sites excluding the subset of sites.

According to some embodiments, the method further includes tuning the wafer manufacturing process, based on the determined quality/attribute.

According to some embodiments, generating a reconstruction of the 3D structural element includes generating a section view of the one or more 3D structural elements.

According to some embodiments, the subset of sites includes no more than about 5%, about 2% or about 1% of an area of the wafer. Each possibility is a separate embodiment.

According to some embodiments, the predetermined diagonal angle is about 5-25°.

According to some embodiments, the one or more 3D structural elements includes a transistor. According to some embodiments, the transistor is or includes a logic and/or memory device. According to some embodiments, the transistor is a gate-all-around (GAA) transistor comprising one or more nano sheets. According to some embodiments, determining a characteristic and/or dimension includes determining a height and/or width of the nano sheets.

According to some embodiments, the ion beam is a noble gas ion beam.

According to some embodiments, applying the algorithm further includes inputting into the algorithm one or more structural parameters of the deposition layer.

According to some embodiments, the method further includes repeating steps a) and b) to generate a plurality of diagonal cuts in the structural elements and to scan the structural elements after each diagonal cut.

According to some embodiments, generating the reconstruction of the one or more 3D structural elements or a component thereof, in step c), includes applying the algorithm on the images obtained after each diagonal cut.

According to some embodiments, the reconstruction of the one or more 3D structural elements is provided at a resolution of about 1 nm.

According to some embodiments, the SEM is a CFE-SEM.

According to some embodiments, the method further includes selecting an optimal plane rotation (ψ) of the FIB prior to the cutting.

According to some embodiments, the method further includes adjusting/changing the plane rotation (ψ) of the FIB between the cutting of at least some of the plurality of sites.

According to some embodiments, there is provided a FIB-SEM system for metrology of a wafer comprising a plurality of sites, each site comprising one or more 3D structural element, the system including:
a deposition system configured to fill voids in the 3D structural elements of a subset of the plurality of sites, the deposition system including:
   a gas injection system (GIS); and
   an electron gun configured to project an electron beam on the injected gas;
a FIB column configured to project an ion beam at a predetermined mechanical angle (a) and at a controllable plane rotation (w) on the subset of sites, thereby generating a diagonal cut in each of the subset of sites;
a scanning electron microscope (SEM) configured to scan the diagonal cuts to obtain an image at different depths of each of the subset of sites; and
a processor configured to apply an algorithm configured to generate a reconstruction of the 3D structural element in the subset of sites and determining a characteristic and/or dimension of the one or more 3D structural elements and/or the component thereof, based thereon.

According to some embodiments, the system is configured to maintain the integrity of the plurality of sites excluding the subset of sites.

According to some embodiments, generating a reconstruction of the 3D structural element includes generating a section view of the one or more 3D structural elements.

According to some embodiments, the predetermined diagonal angle is about 5-25°.

According to some embodiments, the ion beam is a noble gas ion beam.

According to some embodiments, the system includes an auxiliary SEM. According to some embodiments, the auxiliary SEM includes the electron gun.

According to some embodiments, the SEM is a cold field emission (CFE)-SEM.

According to some embodiments, the system is a stand-alone tool, such that the deposition conducted by the deposition system, the cutting conducted by the FIB column and the scanning conducted by the scanning electron microscope (SEM) is performed during a continuous flow by a single tool.

Certain embodiments of the present disclosure may include some, all, or none of the above advantages. One or more other technical advantages may be readily apparent to those skilled in the art from the figures, descriptions, and claims included herein. Moreover, while specific advantages have been enumerated above, various embodiments may include all, some, or none of the enumerated advantages.

Unless otherwise defined, all technical and scientific terms used herein have the same meaning as commonly understood by one of ordinary skill in the art to which this disclosure pertains. In case of conflict, the patent specification, including definitions, governs. As used herein, the indefinite articles “a” and “an” mean “at least one” or “one or more” unless the context clearly dictates otherwise.

Unless specifically stated otherwise, as apparent from the disclosure, it is appreciated that, according to some embodiments, terms such as “processing”, “computing”, “calculating”, “determining”, “estimating”, “assessing”, “gauging” or the like, may refer to the action and/or processes of a computer or computing system, or similar electronic computing device, that manipulate and/or transform data, represented as physical (e.g., electronic) quantities within the computing system's registers and/or memories, into other data similarly represented as physical quantities within the computing system's memories, registers or other such information storage, transmission or display devices.

Embodiments of the present disclosure may include apparatuses for performing the operations herein. The apparatuses may be specially constructed for the desired purposes or may include a general-purpose computer(s) selectively activated or reconfigured by a computer program stored in the computer. Such a computer program may be stored in a computer readable storage medium, such as, but not limited to, any type of disk including floppy disks, optical disks, CD-ROMs, magnetic-optical disks, read-only memories (ROMs), random access memories (RAMs), electrically programmable read-only memories (EPROMs), electrically erasable and programmable read only memories (EEPROMs), magnetic or optical cards, or any other type of media suitable for storing electronic instructions, and capable of being coupled to a computer system bus.

The processes and displays presented herein are not inherently related to any particular computer or other apparatus. Various general-purpose systems may be used with programs in accordance with the teachings herein, or it may prove convenient to construct a more specialized apparatus to perform the desired method(s). The desired structure(s) for a variety of these systems appear from the description below. In addition, embodiments of the present disclosure are not described with reference to any particular programming language. It will be appreciated that a variety of programming languages may be used to implement the teachings of the present disclosure as described herein.

Aspects of the disclosure may be described in the general context of computer-executable instructions, such as program modules, being executed by a computer. Generally, program modules include routines, programs, objects, components, data structures, and so forth, which perform particular tasks or implement particular abstract data types. Disclosed embodiments may also be practiced in distributed computing environments where tasks are performed by remote processing devices that are linked through a communications network. In a distributed computing environment, program modules may be located in both local and remote computer storage media including memory storage devices.

### BRIEF DESCRIPTION OF THE DRAWINGS

Some embodiments of the disclosure are described herein with reference to the accompanying figures. The description, together with the figures, makes apparent to a person having ordinary skill in the art how some embodiments may be practiced. The figures are for the purpose of illustrative description and no attempt is made to show structural details of an embodiment in more detail than is necessary for a fundamental understanding of the disclosure.

For the sake of clarity, some objects depicted in the figures are not drawn to scale. Moreover, two different objects in the same figure may be drawn to different scales. In particular, the scale of some objects may be greatly exaggerated as compared to other objects in the same figure.

In the figures:

FIG. 1 is an exemplary flowchart of a method for FIB-SEM 3D inspection of a wafer, according to some embodiments;

FIG. 2A illustratively depicts a wafer site comprising a plurality of 3D structural elements, according to some embodiments;

FIG. 2B illustratively depicts the wafer of FIG. 2A after deposition of a filling material, according to some embodiments;

FIG. 2C illustratively depicts the wafer of FIG. 2B after creation of a diagonal cut with a FIB tool, according to some embodiments;

FIG. 2D illustratively depicts a SEM image of the diagonally cut wafer of FIG. 2C, according to some embodiments;

FIG. 2E is an exemplary reconstruction (section view) of a component of the 3D structural elements of the wafer of FIG. 2A, generated based on the image of FIG. 2D, according to some embodiments;

FIG. 3 is an exemplary raw SEM image of a diagonally cut wafer site;

FIG. 4A illustratively depicts scanning of a plurality of structural element cut with a single diagonal cut, such that each element is cut at a different height (z₁-zₙ) thereof, according to some embodiments;

FIG. 4B is an exemplary a SEM image of a plurality of structural elements cut with a single diagonal cut, such that each element is cut at a different height (z₁-zₙ) thereof, according to some embodiments;

FIG. 5 illustratively depicts scanning of a structural elements delayered by a plurality of diagonal cuts (z₁-zₙ), wherein a SEM image is obtained after each cut, according to some embodiments;

FIG. 6 illustratively depicts a plurality of structural elements milled diagonally with a FIB at a mechanical angle (a) and a plane rotation angle v, according to some embodiments; and

FIG. 7 schematically illustrates a system for FIB-SEM 3D inspection of a wafer, according to some embodiments.

### DETAILED DESCRIPTION OF THE INVENTION

The principles, uses, and implementations of the teachings herein may be better understood with reference to the accompanying description and figures. Upon perusal of the description and figures present herein, one skilled in the art will be able to implement the teachings herein without undue effort or experimentation. In the figures, same reference numerals refer to same parts throughout.

As used herein, the terms “diagonal angle” and mechanical angle may be used interchangeably and refer to the angle of incidence, between an incident beam, e.g., the FIB beam on a surface and the surface itself.

As used herein, the terms “cutting” and “milling” may be used interchangeably and refer to the exposure of internal layers of an element. That is, the ion beam is used to cut trenches or craters into the sample, to give precise, smooth cuts.

As used herein, the term “site” may refer to an area of a wafer. According to some embodiments, the term site may refer to a chip of a wafer.

As used herein the term “subset of sites” may refer to a small number of chips (e.g., 1, 2, 3, 5, or 10 chips) sacrificed for inspection.

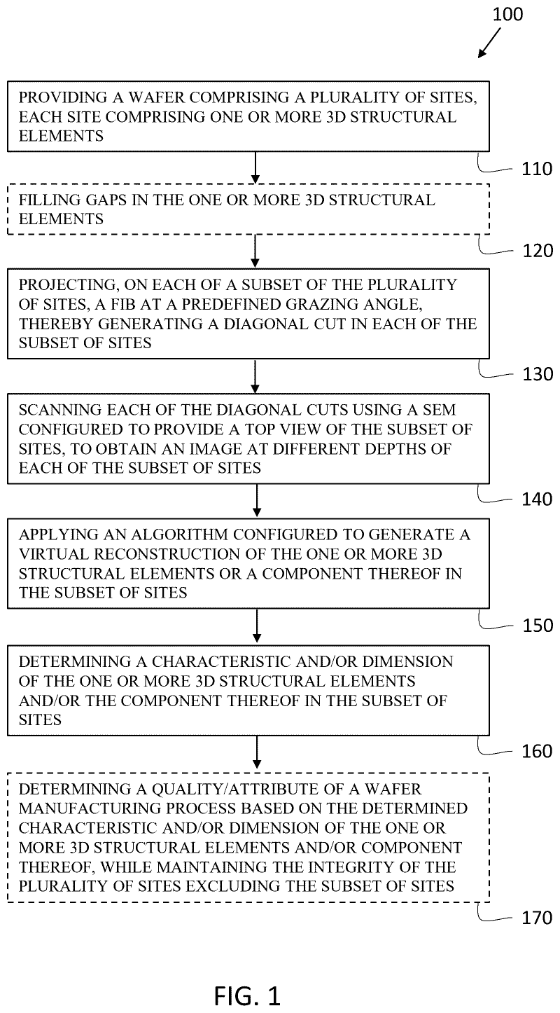

Reference is now made to FIG. 1, which depicts the flow of the herein disclosed method 100 for FIB-SEM 3D inspection of a wafer, according to some embodiments.

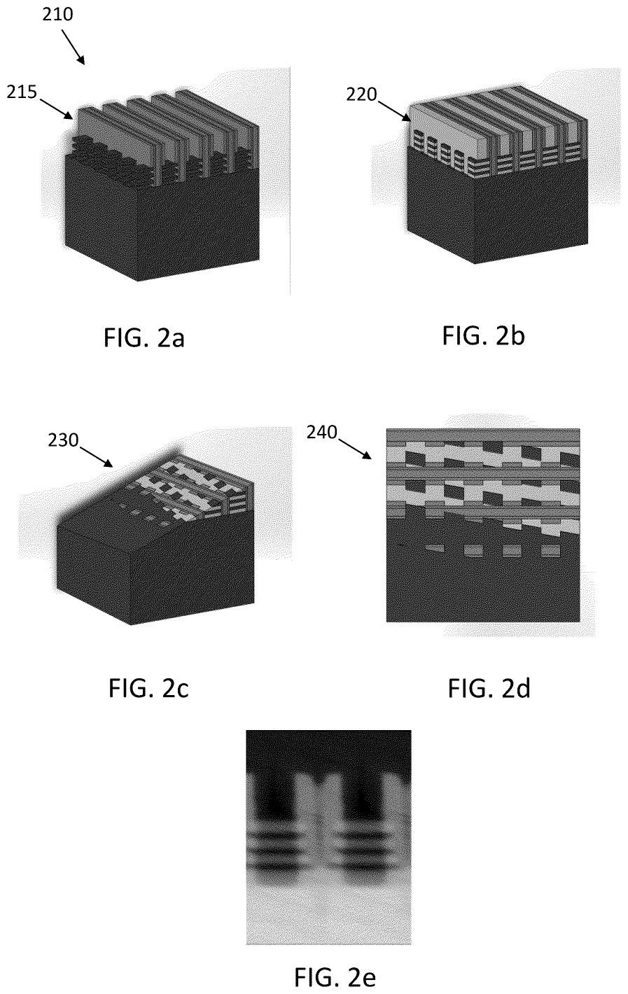

In step 110 of FIG. 1, a wafer comprising a plurality of sites is provided. Each site, such as site 210 shown in FIG. 2A, includes one or more 3D structural elements 215, such as but not limited to a plurality of gate-all-around (GAA) transistors.

In step 120 of FIG. 1, gaps in the one or more 3D structural elements are filled with a filling material 220 (shown in FIG. 2B), optionally by using e-beam assisted deposition.

In step 130 of FIG. 1, a focused ion beam (FIB) is projected on each of a subset of the plurality of sites, at a predefined diagonal angle, thereby generating a diagonal cut 230 in each of the subset of sites, such that each individual structure is seen at a different height, as illustrated in FIG. 2C. According to some embodiments, the ion beam may be a high current beam (e.g., a few pA to several μA).

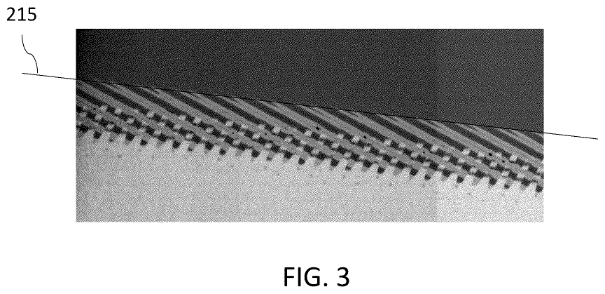

In step 140 of FIG. 1, diagonal cuts 240 are scanned using a scanning electron microscope (SEM) configured to provide a top view of the subset of sites, as illustrated in FIG. 2D. An exemplary raw image of a diagonal cut is shown in FIG. 3 in which line 300 represents an equi-height line.

In step 150 of FIG. 1, a reconstruction 250 of the 3D structural element is created (as shown in FIG. 2E).

In step 160 of FIG. 1, a characteristic and/or dimension of the reconstructed 3D structural element and/or a component thereof is measured.

Optionally in step 170 of FIG. 1, a quality/attribute of an associated wafer manufacturing process is determined, based on the determined characteristic and/or dimension of the reconstructed 3D structural elements and/or component thereof.

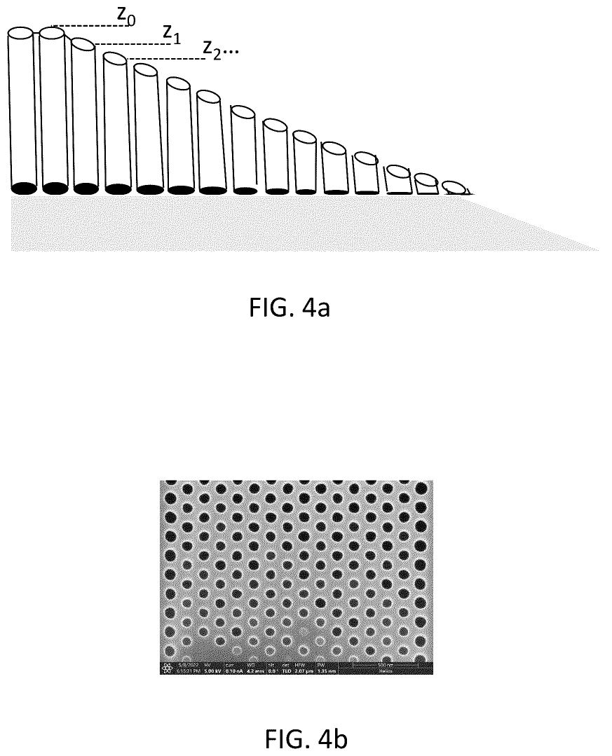

According to some embodiments, when the 3D structure is periodic, a single diagonal cut can be utilized for full 3D reconstruction. In this case, the scanning image includes a plurality of structures cut at a different height (z₁-zₙ), as shown in FIG. 4A, and the structure is reconstructed by composing the shape from different heights. Advantageously, this approach enables to sample a structure in all heights in a single scan, as illustrated in FIG. 4B.

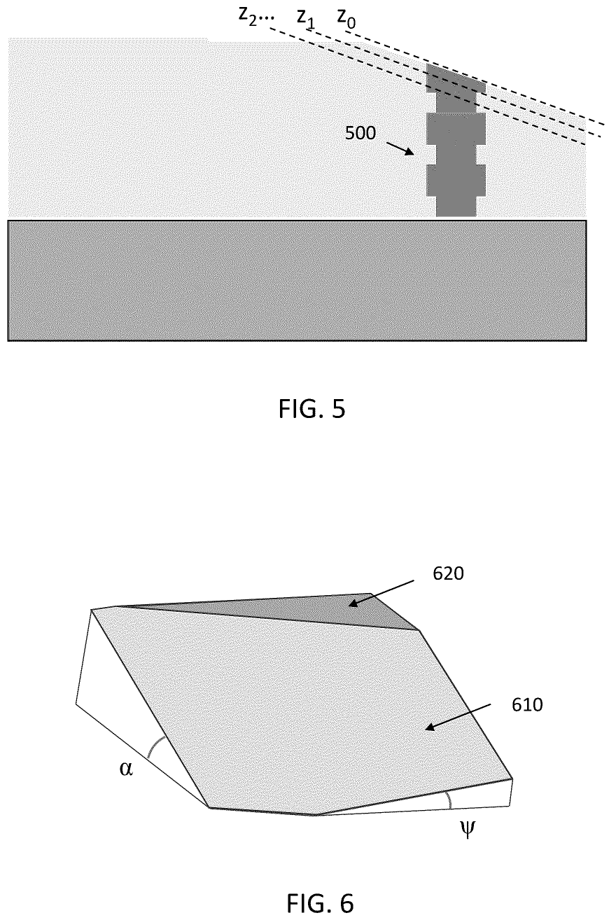

Alternatively, in order to increase resolution and/or if the 3D structural elements are non-periodic, multiple diagonal cuts can be made to delayer the structure, as shown in FIG. 5. In this case, each image reflects a cut made at a different height (z₁-zₙ) and each isolated structural element, such as structural element 500, is reconstructed based on a set of images, each image is obtained after each cut.

Reference is now made to FIG. 6, which illustratively depicts a plurality of structural elements milled diagonally with the slope 610 defined by the FIB mechanical angle α and a plane rotation angle ψ, relative to the wafer plane 620, according to some embodiments. Advantageously, by controlling both mechanical angles α and ψ, the surface that is exposed to the SEM imaging can be controlled for optimal 3D sampling of the volume.

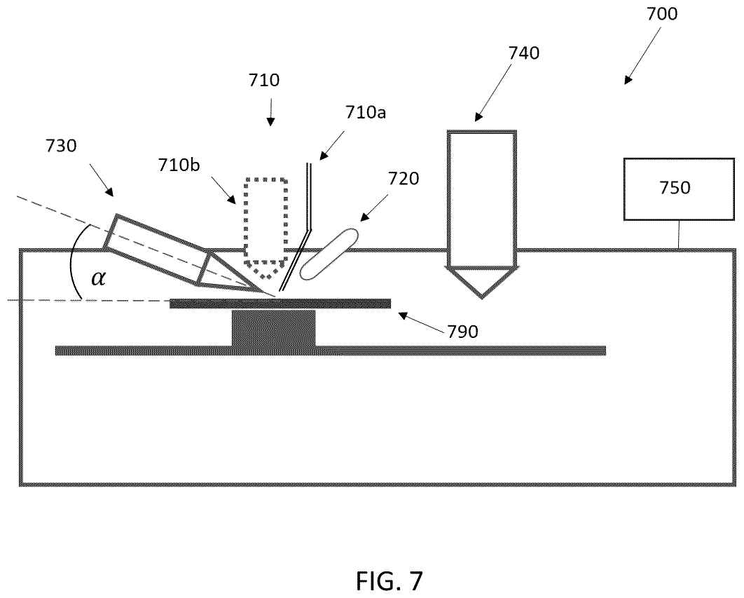

Reference is now made to FIG. 7, which schematically illustrates a system 700 for FIB-SEM 3D inspection/metrology of a wafer 790, according to some embodiments. Advantageously, FIB-SEM system 700 may, according to some embodiments, be integral to/in-line with the manufacturing process, i.e., system 700 may serve as a stand-alone tool for the entire 3D inspection/metrology process.

System 700 includes a deposition system 710 configured to fill voids in the 3D structural elements (not shown) of a chosen area of wafer 790 and provide a layer for FIB milling and consequent imaging of the 3D structural elements. According to some embodiments, and as here illustrated, deposition system 710 may include a gas injection system (GIS) 710a, and an electron gun 710b (auxiliary SEM), optionally in the form of a flood gun, an electrostatic SEM or other low resolution SEM. Electron gun 710b is configured to project an electron beam on the gas injected by GIS 710a, to thereby cause deposition of a filling material in voids found in the 3D structural elements of the chosen area of wafer 790.

According to some embodiments, the chosen area of the area may constitute 0.01-20% of the wafer area, 0.1-10% of the wafer area, or 0.1-5% of the wafer area, 1-5% of the wafer area. Advantageously, this may enable to damage only a small portion of the wafer.

According to some embodiments, system 700 may further include one or more additional detectors (here illustrated as detector 720) configured to provide additional information. According to some embodiments, the one or more additional detectors may be or include atomic force microscopy (AFM), Energy-dispersive X-ray spectroscopy and/or secondary ions detectors.

System 700 further includes a FIB column 730 configured to project an ion beam at a predetermined diagonal angle (a) (also referred to herein as “mechanical angle) so as to generate a diagonal cut in an area of a wafer which includes 3D structural elements, such that each structural elements is cut at a different height thereof. According to some embodiments, the diagonal angle of FIB column 730 may be in a range of 5-25°.

System 700 further includes a scanning electron microscope (SEM) 740 configured to scan the diagonal cut so as to obtain one or more images of the structural elements, cut at the different heights thereof. According to some embodiments SEM 740 may be a cold field emission (CFE)-SEM, which allows measuring the surface with low-energy electrons, which in turn advantageously provide high depth resolution, and high lateral-resolution.

System 700 is functionally associated with a processor 750 configured to apply an algorithmic model on the SEM image(s) to thereby generate a reconstruction of the 3D structural element.

According to some embodiments, processor 750 may be further configured to determine a characteristic and/or a dimension of the 3D structural elements and/or the component thereof.

According to some embodiments, processor 750 may be further configured to determine a quality and/or attribute of the manufacturing process of wafer 790, based on the determined characteristic and/or dimension of the 3D structural elements and/or component thereof.

As used herein, the term “substantially” may be used to specify that a first property, quantity, or parameter is close or equal to a second or a target property, quantity, or parameter. For example, a first object and a second object may be said to be of “substantially the same length”, when a length of the first object measures at least 80% (or some other pre-defined threshold percentage) and no more than 120% (or some other pre-defined threshold percentage) of a length of the second object. In particular, the case wherein the first object is of the same length as the second object is also encompassed by the statement that the first object and the second object are of “substantially the same length”.

According to some embodiments, the target quantity may refer to an optimal parameter, which may in principle be obtainable using mathematical optimization software. Accordingly, for example, a value assumed by a parameter may be said to be “substantially equal” to the maximum possible value assumable by the parameter, when the value of the parameter is equal to at least 80% (or some other pre-defined threshold percentage) of the maximum possible value. In particular, the case wherein the value of the parameter is equal to the maximum possible value is also encompassed by the statement that the value assumed by the parameter is “substantially equal” to the maximum possible value assumable by the parameter.

As used herein, the term “about” may be used to specify a value of a quantity or parameter (e.g., the length of an element) to within a continuous range of values in the neighborhood of (and including) a given (stated) value. According to some embodiments, “about” may specify the value of a parameter to be between 80% and 120% of the given value.

For example, the statement “the length of the element is equal to about 1 m” is equivalent to the statement “the length of the element is between 0.8 m and 1.2 m”. According to some embodiments, “about” may specify the value of a parameter to be between 90% and 110% of the given value. According to some embodiments, “about” may specify the value of a parameter to be between 95% and 105% of the given value.

As used herein, according to some embodiments, the terms “substantially” and “about” may be interchangeable.

It is appreciated that certain features of the disclosure, which are, for clarity, described in the context of separate embodiments, may also be provided in combination in a single embodiment. Conversely, various features of the disclosure, which are, for brevity, described in the context of a single embodiment, may also be provided separately or in any suitable sub-combination or as suitable in any other described embodiment of the disclosure. No feature described in the context of an embodiment is to be considered an essential feature of that embodiment, unless explicitly specified as such.

Although operations in disclosed methods, according to some embodiments, may be described in a specific sequence, methods of the disclosure may include some or all of the described operations carried out in a different order. A method of the disclosure may include a few of the operations described or all of the operations described. No particular operation in a disclosed method is to be considered an essential operation of that method, unless explicitly specified as such.

Although the disclosure is described in conjunction with specific embodiments thereof, it is evident that numerous alternatives, modifications and variations that are apparent to those skilled in the art may exist. Accordingly, the disclosure embraces all such alternatives, modifications and variations that fall within the scope of the appended claims.

It is to be understood that the disclosure is not necessarily limited in its application to the details of construction and the arrangement of the components and/or methods set forth herein. Other embodiments may be practiced, and an embodiment may be carried out in various ways.

The phraseology and terminology employed herein are for descriptive purpose and should not be regarded as limiting. Citation or identification of any reference in this application shall not be construed as an admission that such reference is available as prior art to the disclosure. Section headings are used herein to ease understanding of the specification and should not be construed as necessarily limiting.

While certain embodiments of the invention have been illustrated and described, it will be clear that the invention is not limited to the embodiments described herein. Numerous modifications, changes, variations, substitutions, and equivalents will be apparent to those skilled in the art without departing from the spirit and scope of the present invention as described by the claims, which follow.

What is claimed is:

1. A method for metrology of a wafer comprising a plurality of sites each site comprising one or more 3D structural elements, the method comprising the steps of:
a. depositing, on each of a subset of the plurality of sites, a deposition layer using a gas injection system (GIS) and a charged-particle gun,
b. projecting, on each of a subset of the plurality of sites, a focused ion beam (FIB) at a predefined mechanical angle (a) and at a controllable plane rotation (w), thereby generating a diagonal cut in each of the subset of sites,
c. scanning each of the diagonal cuts using a scanning electron microscope (SEM) configured to provide a top view of the subset of sites, to obtain an image at different depths of each of the subset of sites;
d. applying an algorithm on the image, the algorithm configured to generate a reconstruction of the one or more 3D structural elements or a component thereof in the subset of sites;
e. determining a characteristic and/or dimension of the one or more 3D structural elements and/or the component thereof in the subset of sites; and
f. determining a quality/attribute of a wafer manufacturing process based on the determined characteristic and/or dimension of the one or more 3D structural elements and/or component thereof, while maintaining the integrity of the plurality of sites excluding the subset of sites.

2. The method of claim 1, further comprising tuning the wafer manufacturing process, based on the determined quality/attribute.

3. The method of claim 1, wherein generating a reconstruction of the 3D structural element comprises generating a section view of the one or more 3D structural elements.

4. The method of claim 1, wherein the subset of sites comprises no more than about 5% of an area of the wafer.

5. The method of claim 1, wherein the predetermined diagonal angle is about 5-25°.

6. The method of claim 1, wherein the one or more 3D structural elements comprises a gate-all-around (GAA) transistor comprising one or more nano sheets.

7. The method of claim 6, wherein determining a characteristic and/or dimension comprises determining a height and/or width of the nano sheets.

8. The method of claim 1, wherein the ion beam is a noble gas ion beam.

9. The method of claim 1, wherein applying the algorithm further comprises inputting into the algorithm one or more structural parameters of the deposition layer.

10. The method of claim 1, further comprising repeating steps a) and b) to generate a plurality of diagonal cuts in the structural elements and to scan the structural elements after each diagonal cut.

11. The method of claim 10, wherein generating the reconstruction of the one or more 3D structural elements or a component thereof, in step c), comprises applying the algorithm on the images obtained after each diagonal cut.

12. The method of claim 1, wherein the reconstruction of the one or more 3D structural elements is provided at a resolution of about 1 nm.

13. The method of claim 1, wherein the SEM is a CFE-SEM.

14. The method of claim 1, further comprising selecting an optimal plane rotation (w) of the FIB prior to the cutting.

15. The method of claim 14, further comprising adjusting/changing the plane rotation (w) of the FIB between the cutting of at least some of the plurality of sites.

16. A FIB-SEM system for metrology of a wafer comprising a plurality of sites, each site comprising one or more 3D structural element, the system comprising:
a. a deposition system configured to fill voids in the 3D structural elements of a subset of the plurality of sites, the deposition system comprising:
i. a gas injection system (GIS); and
ii. an electron gun configured to project an electron beam on the injected gas;
b. a FIB column configured to project an ion beam at a predetermined mechanical angle (α) and at a controllable plane rotation (ψ) on the subset of sites, thereby generating a diagonal cut in each of the subset of sites;
c. a scanning electron microscope (SEM) configured to scan the diagonal cuts to obtain an image at different depths of each of the subset of sites; and
d. a processor configured to apply an algorithm configured to generate a reconstruction of the 3D structural element in the subset of sites and determining a characteristic and/or dimension of the one or more 3D structural elements and/or the component thereof, based thereon,
wherein the system is configured to maintain the integrity of the plurality of sites excluding the subset of sites.

17. The system of claim 16, wherein generating a reconstruction of the 3D structural element comprises generating a section view of the one or more 3D structural elements.

18. The system of claim 16, comprising an auxiliary SEM, and wherein the auxiliary SEM comprises the electron gun.

19. The system of claim 16, wherein the SEM is a cold field emission (CFE)-SEM.

20. The system of claim 16, is a stand-alone tool, such that the deposition conducted by the deposition system, the cutting conducted by the FIB column and the scanning conducted by the scanning electron microscope (SEM) is performed during a continuous flow by a single tool.
